(19) United States
(12) Patent Application Publication
(10) Pub. No.: US 2017/0092480 A1
(43) Pub. Date: Mar. 30, 2017

(54) METHOD AND APPARATUS FOR MANUFACTURING A SEMICONDUCTOR DEVICE

(71) Applicant: Samsung Electronics Co., Ltd., Suwon-si (KR)

(72) Inventors: In-Sun YI, Seoul (KR); Ki-Chul KIM, Seongnam-si (KR); Jong-Cheol LEE, Seoul (KR); Kyu-Hee HAN, Suwon-si (KR); Jae-Chul SHIN, Goyang-si (KR); Min-Hwa JUNG, Hwaseong-si (KR); Yu-Ho Won, Hwaseong-si (KR); Seung-Han LEE, Osan-si (KR); Jin-Pil HEO, Pyeongtaek-si (KR)

(21) Appl. No.: 15/000,001

(22) Filed: Jan. 18, 2016

(30) Foreign Application Priority Data
Jan. 20, 2015 (KR) 10-2014-0009131

(51) Int. Cl. H01L 21/02; C23C 16/458; C23C 16/455

(52) U.S. Cl. CPC H01L 21/0228; H01L 21/0262; C23C 16/45544; C23C 16/458

(57) ABSTRACT

Provided are gas injection apparatuses, thin-film deposition equipment, and methods for manufacturing a semiconductor device. The gas injection apparatus includes: a base plate; a first gas separation region on the base plate; first and second source gas supplying regions disposed on the base plate to either side of the first gas separation region, respectively, and configured to supply a source gas; and a first reaction gas supplying region disposed at a position on the base plate other than between the first gas separation region and the first source gas supplying region and between the first gas separation region and the second source gas supplying region, and configured to supply a reaction gas, wherein the first source gas supplying region and the second source gas supplying region protrude from the base plate, wherein each of the first source gas supplying region and the second source gas supplying region has a fan-shaped upper face, and wherein the first gas separation region is defined by a side wall of the first source gas supplying region and a side wall of the second source gas supplying region, the side walls facing each other and extending in radial directions.

This application claims priority to Korean Patent Application No. 10-2015-0009131 filed on Jan. 20, 2015 in the Korean Intellectual Property Office, the disclosure of which is incorporated herein by reference in its entirety.

### BACKGROUND

1. Technical Field

The present disclosure relates to a gas injection apparatus and a thin-film deposition equipment including the same. The present disclosure also relates to a gas injection apparatus capable of supplying two species of gas reacting with each other into a chamber sequentially, and a thin-film deposition equipment including the same.

2. Description of the Related Art

As a thin-film deposition method in semiconductor manufacturing processes, there is a known process for forming a thin-film on a substrate or the like by repeating a cycle involving supplying a first reaction gas in a vacuum state so that it is absorbed on a surface of the substrate, then changing the gas with a second reaction gas so that it reacts with the first reaction gas on the surface, so that single or multiple, atomic or molecular layers are formed on the surface. This process is known as ALD (Atomic Layer Deposition) or MLD (Molecular Layer Deposition), for example, and is hereinafter referred to as ALD. The ALD method is believed to be a technique that can effectively respond to the recent trend of semiconductor devices that are ever becoming thinner, in that it can control film thickness with high precision by adjusting the number of cycles, and also exhibits good in-plane uniformity of film quality.

As such a thin-film deposition method, a method has been discussed in which a reaction gas is supplied onto a substrate from the top using a single-wafer processing equipment having a gas shower head at the center of the top of a vacuum chamber, and the reaction gas which did not contribute to the reaction along with reaction by-product are discharged through the lower side of the chamber. According to this method, however, when changing the first reaction gas with a second reaction gas or vice versa, a purging process is carried out using a purge gas, which takes a relatively long time, and the number of cycles is sometimes up to hundreds of times. This may consume significant time in layering. For this reason, there is the demand for an apparatus and/or a method can perform such processes with high throughput.

### SUMMARY

Aspects of the present disclosure provide a gas injection apparatus capable of improving absorption efficiency of gas onto a substrate.

Aspects of the present disclosure also provide a thin-film deposition equipment capable of improving absorption efficiency of gas onto a substrate.

In accordance with an aspect of the present disclosure, an apparatus comprises a base plate, a first gas separation region on the base plate, first and second source gas supplying regions disposed on the base plate on either side of the first gas separation region, respectively, and configured to supply source gas and a first reaction gas supplying region disposed at a position on the base plate other than between the first gas separation region and the first source gas supplying region or between the first gas separation region and the second source gas supplying region, and configured to supply reaction gas, wherein the first source gas supplying region and the second source gas supplying region protrude from the base plate, wherein each of the first source gas supplying region and the second source gas supplying region has a fan-shaped, upper face, and wherein the first gas separation region is defined by a side wall of the first source gas supplying region and a side wall of the second source gas supplying region, the side walls facing each other and extending in radial directions.

In accordance with another aspect of the present disclosure, an apparatus comprises a base plate including first to fourth gas supplying regions disposed on the base plate arranged sequentially in a circumferential direction, a first trench extending in a radial direction between the first gas supplying region and the second gas supplying region and having the base plate as its bottom, a second trench extending in the a radial direction between the second gas supplying region and the third gas supplying region and having the base plate as its bottom, a third trench extending in the a radial direction between the third gas supplying region and the fourth gas supplying region and having the base plate as its bottom, a fourth trench extending in the a radial direction between the fourth gas supplying region and the first gas supplying region and having the base plate as its bottom and a central trench surrounded by the first to fourth gas supplying regions and having its bottom defined by the base plate, wherein the first gas supplying region supplies a source gas, the third gas supplying region supplies a reaction gas, and the second and fourth gas supplying regions supply a purge gas, and wherein the first gas supplying region comprises: first and second source gas supplying regions for supplying the source gas, and a first gas separation region disposed between the first source gas supplying region and the second source gas supplying region and configured not to supply the source gas.

In accordance with still another aspect of the present disclosure, an apparatus comprises a vacuum chamber comprising a top plate and a body, and a susceptor installed in the vacuum chamber, configured to rotate therein, and having a portion configured to load a wafer on a first face, wherein the top plate comprises a base plate facing the susceptor and having a second face opposite to the first face of the susceptor, first to fourth regions disposed on the second face of the base plate arranged sequentially in a rotating direction of the susceptor, a first recess extending in a radial direction between the first region and the second region and having the base plate as its bottom, a second recess extending in the a radial direction between the second region and the third region and having the base plate as its bottom, a third recess extending in the a radial direction between the third region and the fourth region and having the base plate as its bottom and a fourth recess extending in the a radial direction between the fourth region and the first region and having the base plate as its bottom, wherein the first region is configured to supply a source gas onto the first face of the susceptor, the third region is configured to supply a reaction gas onto the first face of the susceptor, and the second and fourth regions are configured to supply a purge gas, wherein the first region comprises first, second, and third sub-regions arranged sequentially in the rotating direction of the susceptor, and wherein the first and third sub-regions are configured to supply the source gas onto the first face of the susceptor, while the second sub-region does not supply the source gas.

The third region may comprise first, second and third sub-regions arranged sequentially in the rotating direction of the susceptor. The first and third sub-regions may be configured to supply the reaction gas onto the first face of the susceptor while the second sub-region may not supply the reaction gas. The second sub-regions of the first and third regions may be configured to supply a purge gas. The second and fourth regions may be configured to supply a purge gas. The top plate may further comprise a fifth recess in the center portion of the top plate, and the first to fourth recesses are connected to each other via the fifth recess. The first to fourth regions may be fan-shaped. The first to fourth recesses may be fan-shaped, and the fifth recess may be circular.

In accordance with an aspect of the present disclosure, a method of manufacturing a semiconductor device includes a step of providing a substrate on a susceptor of a thin film deposition equipment having a gas injection head, a step of providing a source gas on the substrate from a first gas supplying region of the gas injection head, a step of providing a purge gas on the substrate from a second gas supplying region of the gas injection head, and a step of providing a reaction gas on the substrate from a third gas supplying region of the gas injection head, wherein the source gas and the reaction gas form a layer on the substrate and remaining source gas or reaction gas is discharged through a first recess formed on the gas injection head and a pumping port connected to the outside of the thin film deposition equipment.

The first recess may be formed in the first gas supplying region of the gas injection head and the first gas supplying region may include a first source gas supplying region and a second source gas supplying region disposed on either side of the first recess. A second recess may be formed in the third gas supplying region of the gas injection head and the third gas supplying region may include a first reaction gas supplying region and a second reaction gas supplying region disposed on either side of the second recess, and the remaining reaction gas may be discharged through the second recess.

A second recess may be formed between the first gas supplying region and the second gas supplying region, and the purge gas may be discharged through the second recess. The first recess may be formed between the first gas supplying region and the second gas supplying region. The method may further include a step of providing a purge gas on the substrate from a fourth gas supplying region of the gas injection head, wherein the first recess may be formed between two of the first, second, third and fourth gas supplying regions of the gas injection head. The gas injection head may include a second recess formed between two of the first, second, third and fourth gas supplying regions, and a central recess connecting the first recess and the second recess of the gas injection head.

In one aspect of the disclosure, a method of manufacturing a semiconductor device may include steps of providing a substrate on a susceptor of a thin film deposition equipment having a gas injection head, providing a source gas on the substrate from the gas injection head, and providing a reaction gas on the substrate from the gas injection head after providing the source gas on the substrate, wherein the gas injection head may include a base plate, a first gas separation region on the base plate, a first and a second source gas supplying regions disposed on either side of the first gas separation region and configured to supply a source gas, and a first reaction gas supplying region disposed on the base plate other than between the first gas separation region and the first source gas supplying region and between the first gas separation region and the second source gas supplying region, and configured to supply a reaction gas, wherein the first source gas supplying region and the second source gas supplying region protrude from the base plate, wherein each of the first source gas supplying region and the second source gas supplying region has a fan-shaped, upper face, and wherein the first gas separation region is defined by a side wall of the first source gas supplying region and a side wall of the second source gas supplying region, the side walls facing each other and extending in radial directions.

The first gas separation region may be configured to supply a purge gas. The gas injection head may further include a second reaction gas supplying region disposed at a position other than between the first gas separation region and the first source gas supplying region and between the first gas separation region and the second source gas supplying region, and a second gas separation region, wherein the second reaction gas supplying region may be configured to supply a reaction gas, and wherein the second gas separation region may be disposed between the first reaction gas supplying region and the second reaction gas supplying region. The second gas separation region may be configured to supply a purge gas. The first reaction gas supplying region and the second reaction gas supplying region may protrude from the base plate, wherein an upper face of the first reaction gas supplying region and an upper face of the second reaction gas supplying region may have a fan shape, and wherein the second gas separation region may be defined by a side wall of the first reaction gas supplying region and a side wall of the second reaction gas supplying region, the side walls facing each other and extending in radial directions. The gas injection head may further include a second gas separation region disposed between the first source gas supplying region and the first reaction gas supplying region, and a third gas separation region disposed between the second source gas supplying region and the first reaction gas supplying region, wherein the second gas separation region and the third gas separation region may be configured to supply a purge gas. The method may further include a first recess extending in a radial direction between the second gas separation region and the first source gas supplying region and having the base plate as its bottom, a second recess extending in a radial direction between the third gas separation region and the second source gas supplying region and having the base plate as its bottom, a third recess extending in a radial direction between the second gas separation region and the first reaction gas supplying region and having the base plate as its bottom, and a fourth recess extending in a radial direction between the third gas separation region and the first reaction gas supplying region and having the base plate as its bottom. A region for supplying the reaction gas may be disposed at a position neither between the first gas separation region and the first source gas supplying region nor between the first gas separation region and the second source gas supplying region.

According to an aspect of the present disclosure, a method of manufacturing a semiconductor device may include steps of providing a substrate on a susceptor of a thin film deposition equipment having a gas injection head, providing a source gas on the substrate from the gas injection head, and providing a reaction gas on the substrate from the gas injection head after providing the source gas on the substrate, wherein the gas injection head includes, a base plate, first to fourth gas supplying regions disposed on the base plate in first to fourth respective order in a circumferential direction, a first recess extending in a radial direction between the first gas supplying region and the second gas supplying region and having the base plate as its bottom, a second recess extending in a radial direction between the second gas supplying region and the third gas supplying region and having the base plate as its bottom, a third recess extending in a radial direction between the third gas supplying region and the fourth gas supplying region and having the base plate as its bottom, a fourth recess extending in a radial direction between the fourth gas supplying region and the first gas supplying region and having the base plate as its bottom, and a central recess surrounded by the first to fourth gas supplying regions and having its bottom defined by the base plate, wherein the first gas supplying region supplies source gas, the third gas supplying region supplies a reaction gas, and the second and fourth gas supplying regions supply one or more purge gases, and wherein the first gas supplying region comprises a first and a second source gas supplying regions for supplying the source gas, and a first gas separation region disposed between the first source gas supplying region and the second source gas supplying region and configured not to supply the source gas.

The first gas separation region may be configured to supply a purge gas. The third gas supplying region may include a first and a second reaction gas supplying regions and a second gas separation region, wherein the first and second reaction gas supplying regions may be configured to supply the reaction gas, and wherein the second gas separation region is disposed between the first reaction gas supplying region and the second reaction gas supplying region and is configured not to supply the reaction gas. The first gas separation region and the second gas separation region may be configured to supply the purge gas. The purge gas may be supplied from the bottom of each of the first to fourth recesses.

It should be noted that objects of the present disclosure are not limited to the above-described object, and other objects of the present disclosure will be apparent to those skilled in the art from the following descriptions.

### BRIEF DESCRIPTION OF THE DRAWINGS

The above and other aspects and features of the present disclosure will become more apparent by describing exemplary embodiments in detail with reference to the attached drawings, in which:

FIG. 1 is a top view for schematically illustrating a thin-film deposition equipment according to some exemplary embodiments of the present disclosure;

FIG. 2 is an exemplary cross-sectional view taken along line A-A of FIG. 1;

FIG. 3 is a top view for illustrating an example of a gas injection apparatus used in a thin-film deposition equipment according to some exemplary embodiments of the present disclosure;

FIG. 4 is a top view for illustrating another example of a gas injection apparatus used in a thin-film deposition equipment according to some exemplary embodiments of the present disclosure;

FIG. 5 is a top view for illustrating yet another example of a gas injection apparatus used in a thin-film deposition equipment according to some exemplary embodiments of the present disclosure;

FIGS. 6 and 7 are exemplary cross-sectional views taken along line B-B of FIG. 5;

FIG. 8 is a top view for illustrating still another example of a gas injection apparatus used in a thin-film deposition equipment according to some exemplary embodiments of the present disclosure;

FIGS. 9 and 10 are exemplary cross-sectional views taken along line C-C of FIG. 8;

FIGS. 11 and 12 are views for illustrating yet another example of a gas injection apparatus used in a thin-film deposition equipment according to some exemplary embodiments of the present disclosure;

FIGS. 13 and 14 are exemplary cross-sectional views taken along line D-D of FIG. 12;

FIG. 15 is a top view for illustrating yet another example of a gas injection apparatus used in a thin-film deposition equipment according to some exemplary embodiments of the present disclosure; and

FIG. 16 is a top view for illustrating still another example of a gas injection apparatus used in a thin-film deposition equipment according to some exemplary embodiments of the present disclosure.

FIG. 17 is a flowchart illustrating a method of manufacturing an electronic device according to some exemplary embodiments of the present disclosure.

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, or as contacting another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein shall be interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. Unless the context indicates otherwise, these terms are only used to distinguish one element from another element. Thus, for example, a first element, a first component or a first section discussed below could be termed a second element, a second component or a second section without departing from the teachings of the present inventive concept.

The present disclosure will be described with reference to perspective views, cross-sectional views, and/or plan views, in which various embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

As used herein, a semiconductor device may refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, memory card, hard drive including additional components, or a mobile phone, laptop, tablet, desktop, camera, or other consumer electronic device, etc.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not intended to limit the scope of the inventive concept unless otherwise specified. Further, unless defined otherwise, all terms will be interpreted as defined in generally used dictionaries, and should not be interpreted in an idealized or overly formal sense.

Described herein is an apparatus in which a number of wafers are arranged on a substrate support (or a turntable) with equiangular spacing along the rotating direction, first reaction gas spray nozzles and second reaction gas spray nozzles are arranged with equiangular spacing along the rotating direction such that they face the substrate support, and separation gas nozzles are disposed between them, so that the substrate support is rotated in-plane to thereby deposit a thin-film.

According to this ALD apparatus employing such a turntable, it is not necessary to change first reaction gas with second reaction gas and not necessary to perform a purging process, thereby achieving high throughput.

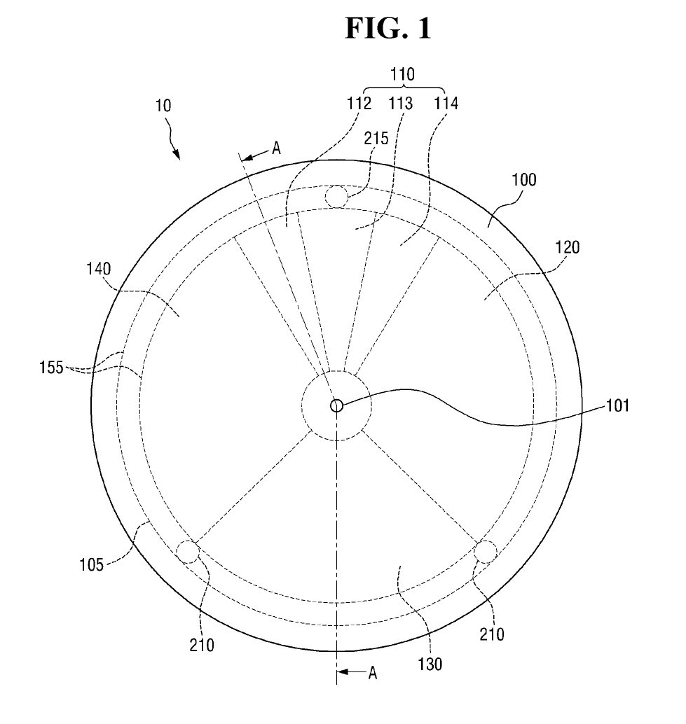

A thin-film deposition equipment according to an exemplary embodiment of the present disclosure will be described with reference to FIGS. 1 to 16.

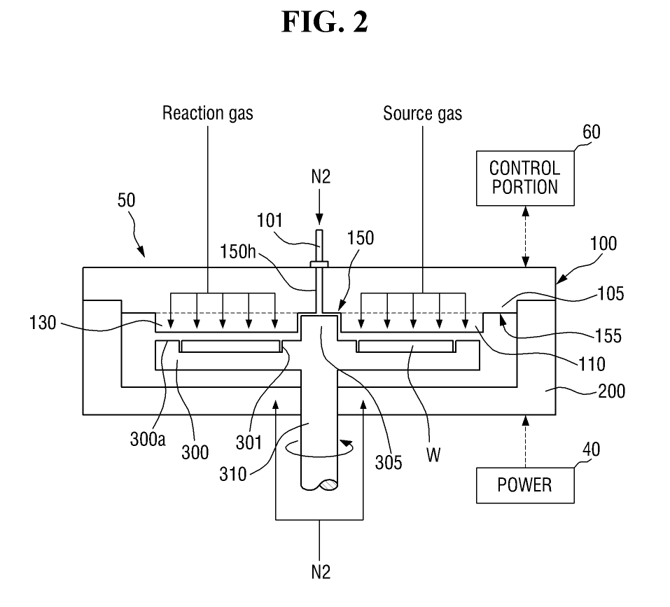

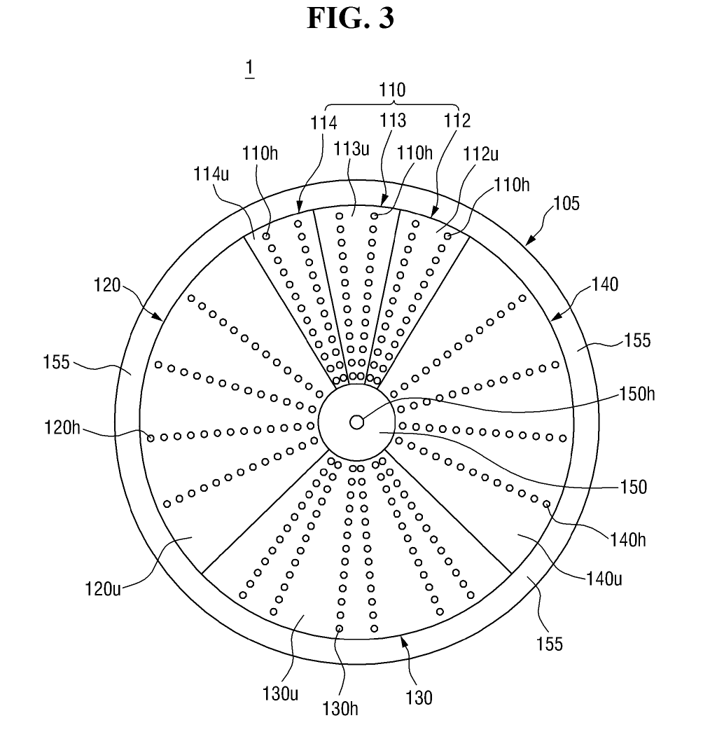

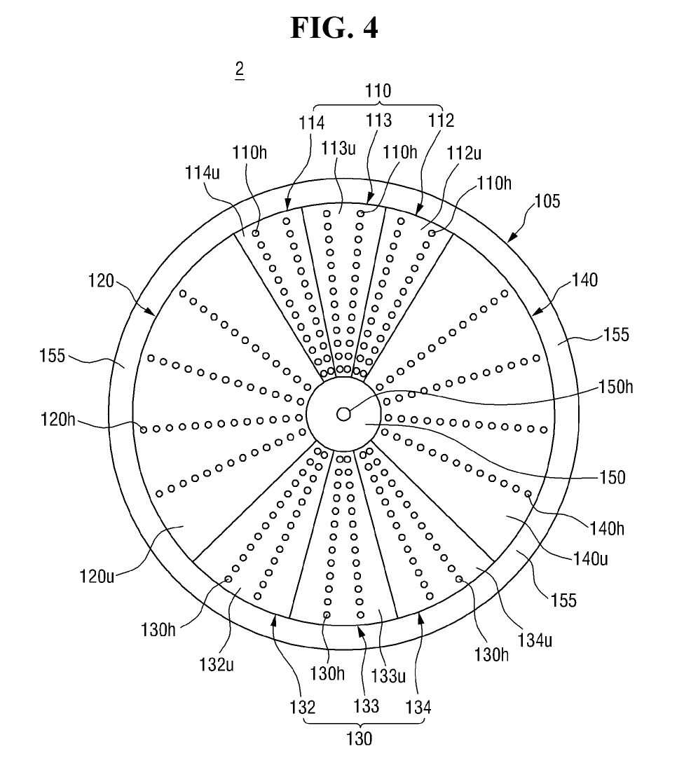

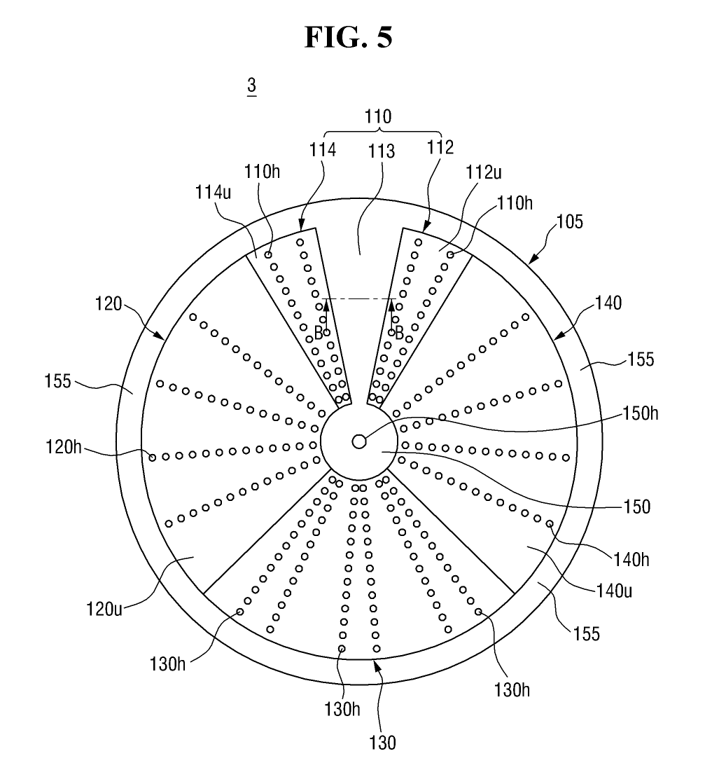

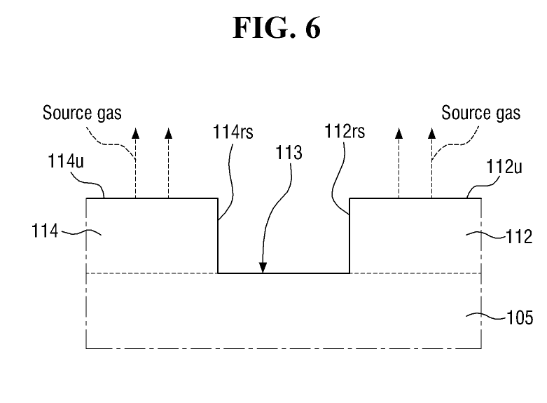

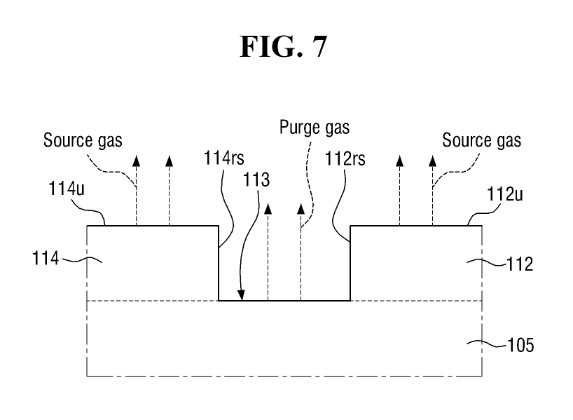

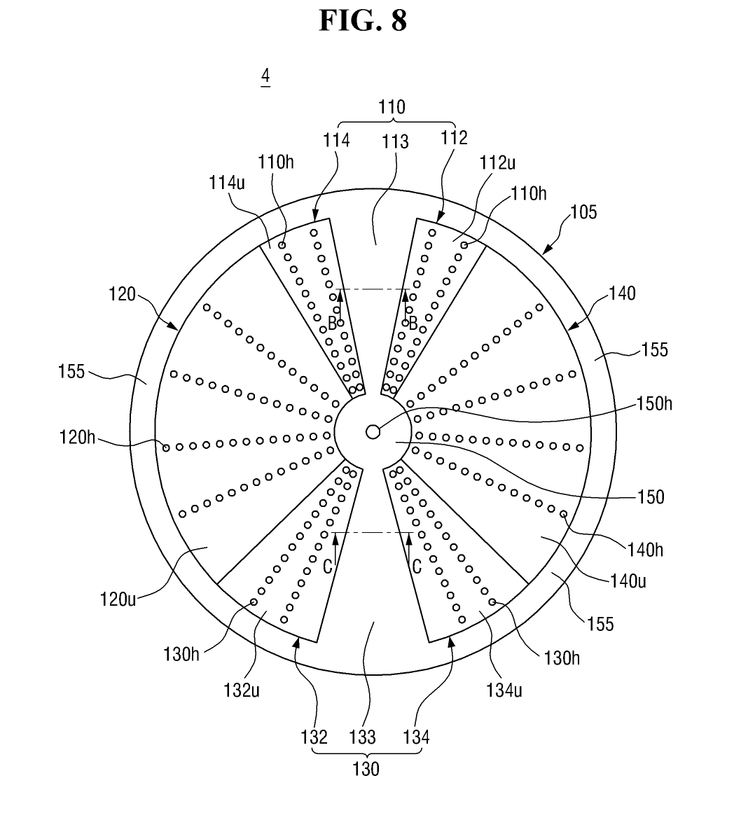

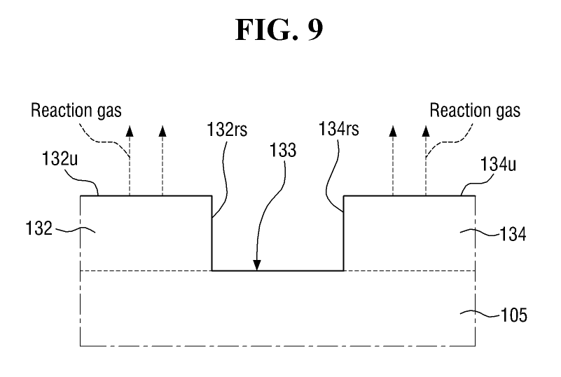

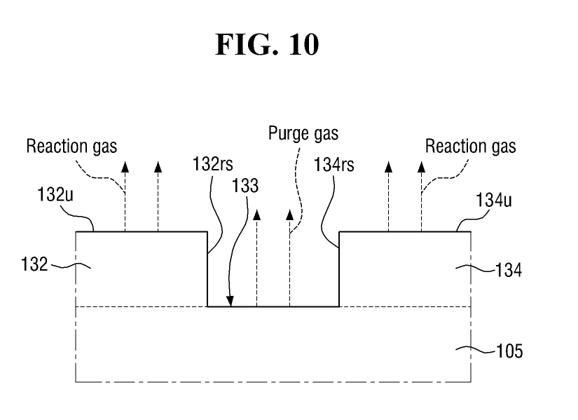

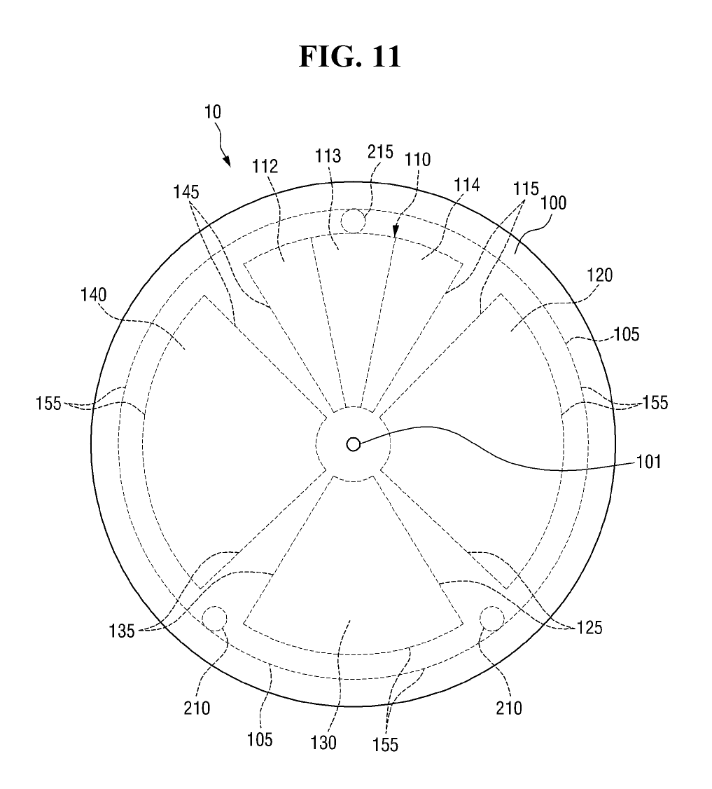

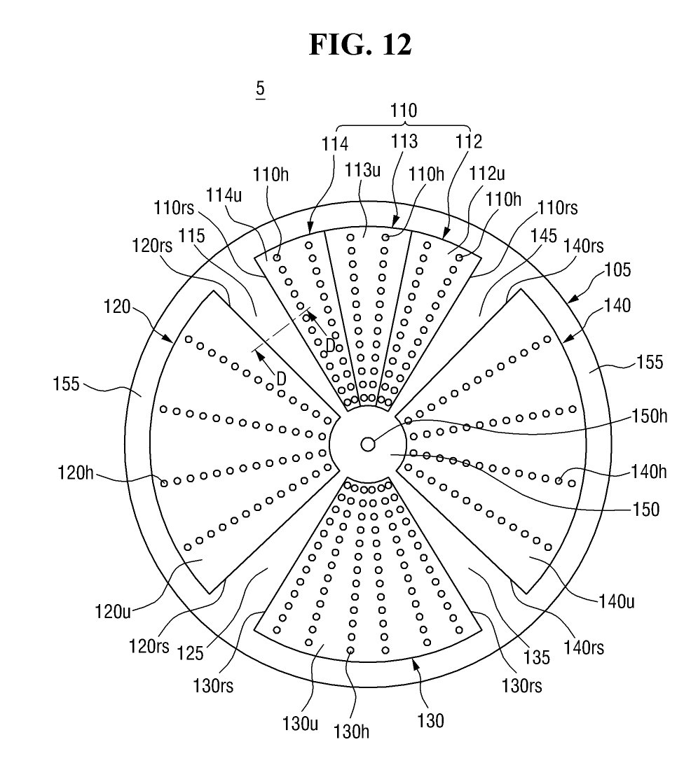

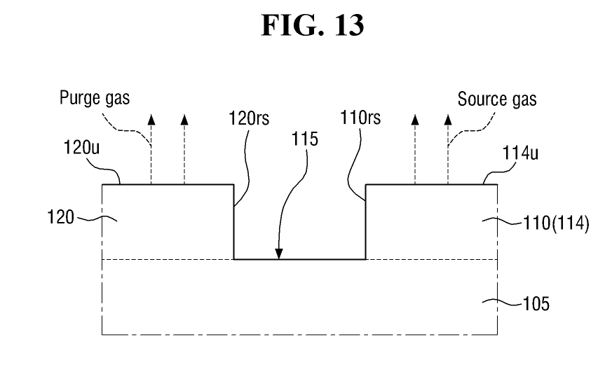

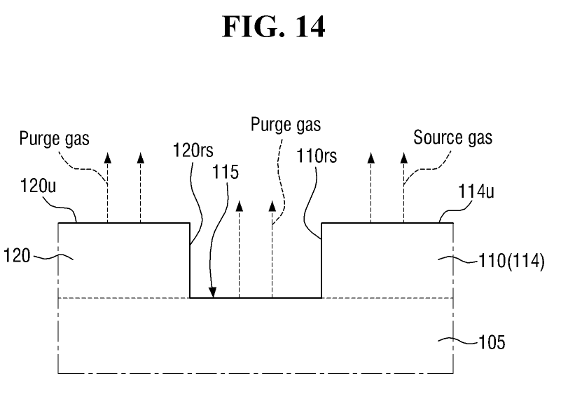

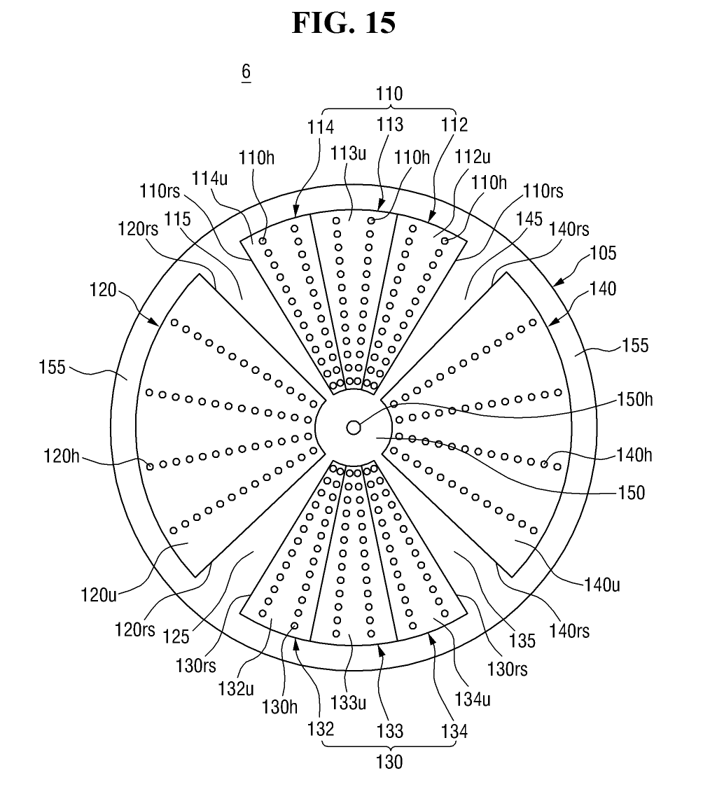

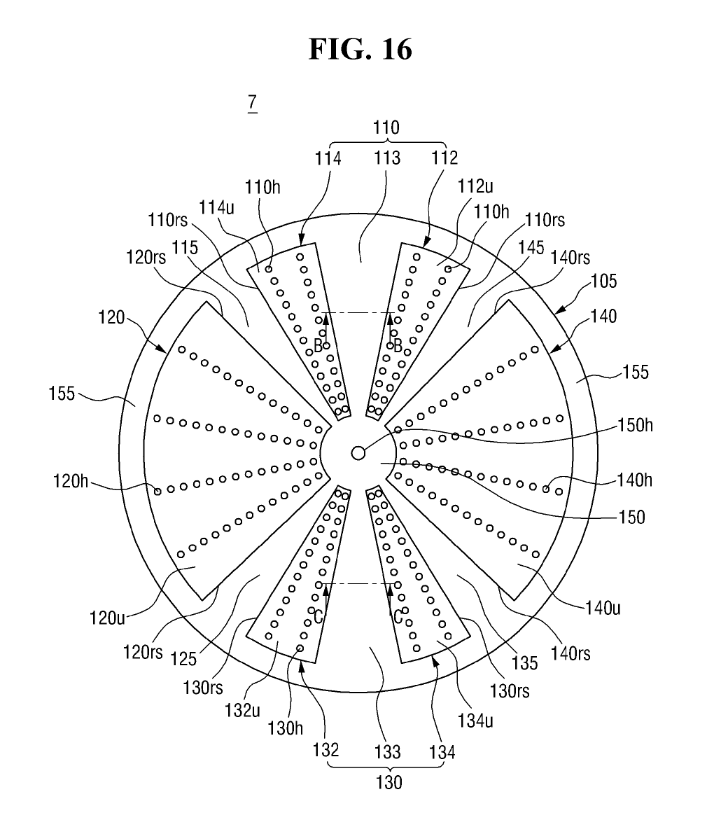

FIG. 1 is a top view for schematically illustrating a thin-film deposition equipment according to an exemplary embodiment of the present disclosure. FIG. 2 is a cross-sectional view taken along line A-A of FIG. 1. FIG. 3 is a top view for illustrating an example of a gas injection apparatus used in a thin-film deposition equipment according to an exemplary embodiment of the present disclosure. FIG. 4 is a top view for illustrating another example of a gas injection apparatus used in a thin-film deposition equipment according to an exemplary embodiment of the present disclosure. FIG. 5 is a top view for illustrating yet another example of a gas injection apparatus used in a thin-film deposition equipment according to an exemplary embodiment of the present disclosure. FIGS. 6 and 7 are cross-sectional views taken along line B-B of FIG. 5. FIG. 8 is a top view for illustrating still another example of a gas injection apparatus used in a thin-film deposition equipment according to an exemplary embodiment of the present disclosure. FIGS. 9 and 10 are cross-sectional views taken along line C-C of FIG. 8. FIGS. 11 and 12 are views for illustrating yet another example of a gas injection apparatus used in a thin-film deposition equipment according to an exemplary embodiment of the present disclosure. FIGS. 13 and 14 are cross-sectional views taken along line D-D of FIG. 12. FIG. 15 is a top view for illustrating yet another example of a gas injection apparatus used in a thin-film deposition equipment according to an exemplary embodiment of the present disclosure. FIG. 16 is a top view for illustrating still another example of a gas injection apparatus used in a thin-film deposition equipment according to an exemplary embodiment of the present disclosure. Each of the gas injection apparatuses described hereinbefore and hereinafter may also be referred to as a gas injection head, or generally referred to as an apparatus. The thin-film deposition equipment described hereinbefore and herein after may be generally referred to as an apparatus.

It is to be noted that FIG. 2 also shows a variety of gas flows supplied into the thin-film deposition equipment 10, along with a power unit 40 and a control portion 60. Further, FIG. 11 is a top view schematically illustrating a thin-film deposition equipment employing the gas injection apparatus shown in FIG. 12.

Referring to FIGS. 1 and 2, a thin-film deposition equipment 10 according to an exemplary embodiment of the present disclosure may include a vacuum chamber 50 and a susceptor 300.

The vacuum chamber 50 may have a generally circular shape when viewed from the above. The vacuum chamber 50 may include a plate-like top plate 100 and a cylinder-like body 200. The shapes of the top plate 100 and the body 200 are illustrative and are not limiting.

The top plate 100 and the body 200 of the vacuum chamber 50 may be separated from each other. The top plate 100 may be attached to the body 200 using, for example, an O-ring, and thereby the vacuum chamber 50 can be sealed in a vacuum state. The top plate 100 can be separated from the body 200 such that the top plate 100 is lifted up by means of a driving mechanism which may be disposed at the outer periphery of a base plate 105.

The top plate 100 and the body 200 may be made of, for example, corrosion-resistant metal. Using such corrosion-resistant metal or the like is helpful to prevent corrosive material from existing in reaction gas used in a thin-film deposition process. However, the material of the top plate 100 and the body 200 is not limited to the corrosion-resistant metal.

The susceptor 300 may be disposed in the vacuum chamber 50. The susceptor 300 may rotate with its rotation axis at the center of the vacuum chamber 50. The susceptor 300 may be installed in the vacuum chamber 50 such that it is rotatable therein.

The susceptor 300 may include a core portion 305 protruding therefrom at the center portion. The core portion 305 may protrude from a face 300a of the susceptor.

The susceptor 300 may include a wafer loading portion 301. The wafer loading portion 301 may be formed on the face 300a of the susceptor 300. For example, the wafer loading portion 301 may be included on the face 300a of the susceptor. The susceptor 300 may include a plurality of wafer loading portions 301. The plurality of wafer loading portions 301 may be, but is not limited to, formed along the periphery of the core portion 305 with regular spacing.

The wafer loading portion 301 may have a circular, recessed shape on the face 300a of the susceptor. The wafer loading portion 301 may have a recessed shape in order to prevent a wafer W from deviating therefrom while the susceptor 300 is rotating.

The susceptor 300 can rotate and may be connected to a rotation shaft 310 extending in the vertical direction. The rotation shaft may penetrate the body 200 from its bottom to be connected to a rotation driving unit.

Although the susceptor 300 in FIG. 2 shows only the wafer loading portion 301 for loading a wafer W, the susceptor 300 may include other elements. For example, the susceptor 300 may include a heating element for adjusting the temperature of a wafer W to a deposition temperature used when a thin-film is deposited on the wafer W.

For example, the top plate 100 may include a gas injection apparatus including the base plate 105 and first to fourth gas supplying regions 110, 120, 130 and 140.

The base plate 105 is disposed such that it faces the susceptor 300. A face of the base plate 105 faces the face 300a of the susceptor. The first to fourth gas supplying regions 110, 120, 130 and 140 may be disposed on the face of the base plate 105 facing the face 300a of the susceptor.

The first gas supplying region 110 may protrude from the face of the base plate 105, and may supply a source gas onto the face 300a of the susceptor. For example, the first gas supplying region 110 may supply a source gas onto a wafer W.

The third gas supplying region 130 may protrude from the face of the base plate 105, and may supply a reaction gas onto the face 300a of the susceptor. For example, the third gas supplying region 130 may supply a reaction gas onto a wafer W.

The second and fourth gas supplying regions 120 and 140 may protrude from the face of the base plate 105, and may supply a purge gas onto the face 300a of the susceptor.

The second gas supplying region 120 and the fourth gas supplying region 140 may serve to discharge the source gas or the reaction gas that is not absorbed on a wafer W to the outside and may act as a fence to prevent the source gas from being mixed with the reaction gas.

The purge gas may be inert gas that does not undergo gas-phase reaction with the source gas or the reaction gas. The purge gas may be, but is not limited to, nitrogen gas.

The first gas supplying region 110 may be connected to a gas port for supplying a source gas, the second gas supplying region 120 and the fourth gas supplying region 140 may be connected to gas ports for supplying a purge gas, and the third gas supplying region 130 may be connected to a gas port for supplying a reaction gas.

In the following descriptions, the source gas is, for example, a metal precursor and the reaction gas is, for example, a non-metal reaction gas that reacts with the metal precursor, for the convenience of illustration.

The first to fourth gas supplying regions 110, 120, 130 and 140 may be disposed in this order along the rotating direction of the susceptor 300. For example, the second gas supplying region 120 and the fourth gas supplying region 140 may be disposed between the first gas supplying region 110 and the third gas supplying region 130, and between the third gas supplying region 130 and the first gas supplying region 110, respectively.

The top plate 100 may include a central trench or depression 150 that is surrounded by the first to fourth gas supplying regions 110, 120, 130 and 140. The central trench or depression 150 has its bottom defined by the face of the base plate 105. The central trench or depression 150 may have a circular shape when viewed from the above. The central trench or depression 150 may also be referred to as a recess. Each of the other trenches and/or depressions described hereinafter may also be referred to as a recess.

The position of the central trench or depression 150 may correspond to the position of the core portion 305 of the susceptor 300. Namely, a part of the core portion 305 may be inserted into the central trench or depression 150.

Additionally, a curtain gas supplying pipe 101 may be connected to the center of the top plate 100 of the vacuum chamber 50. The curtain gas supplying pipe 101 may supply curtain gas into the space between the top plate 100 and the core portion 305.

The curtain gas may prevent the source gas supplied from the first gas supplying region 110 and the reaction gas supplied from the third gas supplying region 130 from diffusing through the space between the top plate 100 and the core portion 305. The curtain gas can prevent the source gas and the reaction gas from being mixed with each other.

For example, the curtain gas can perform a similar role with the purge gas supplied from the second gas supplying region 120 and the fourth gas supplying region 140.

The curtain gas may be inert gas that does not undergo gas-phase reaction with the source gas or the reaction gas. The purge gas may be, but is not limited to, nitrogen gas.

A central spray hole 150h may be formed, for example, at the bottom of the central trench or depression 150. The central spray hole 150h sprays the curtain gas supplied from the curtain gas supplying pipe 101 into the space between the top plate 100 and the core portion 305. Each of the spray holes spraying gases described hereinbefore and hereinafter may also be referred to as a spray nozzle.

Although the central spray hole 150h completely penetrates the top plate 100 in FIG. 2 for the convenience of illustration, it is merely illustrative. For example, the central spray hole 150h may be connected to the curtain gas supplying pipe 101 via a plurality of flow paths formed in the top plate 100.

The curtain gas supplied from the central spray hole 150h flows through the space between the top plate 100 and the core portion 305 to then be pumped out by a first pumping port 215 and/or second pumping ports 210.

The first pumping port 215 and the second pumping ports 210 may be disposed, but is not limited to, at lower portions of the body 200. For example, the first pumping port 215 and the second pumping ports 210 may be disposed at the side portions of the body 200 or at the top plate 100.

The first pumping port 215 and the second pumping ports 210 may be disposed around the susceptor 300 to discharge the source gas and the reaction gas supplied onto a wafer W. For example, the source gas and the reaction gas, which are source materials for thin-film deposition, may be sucked by the first pumping port 215 and the second pumping ports 210, respectively.

For example, the first pumping port 215 may be disposed closely to the first gas supplying region 110, while the second pumping ports 210 may be disposed closely to the third gas supplying region 130.

Although one first pumping port 215 and two second pumping ports 210 are shown in FIG. 1 for the convenience of illustration, this is merely illustrative. For example, two or more first pumping ports 215 may exist and may be disposed at positions where they can efficiently discharge the source gas supplied from the first gas supplying region 110. In certain embodiments, the thin-film deposition equipment 10 may have one, three or more second pumping ports 210. The pumping ports may be disposed at the side portions of the body 200 or at the top plate 100 of the thin-film deposition equipment 10.

For example, if the thin-film deposition equipment according to the exemplary embodiment of the present disclosure is adapted to deposit a ZrO thin-film, Zr precursor and reaction gas containing oxygen (e.g., O₃) remaining after deposition of the ZrO thin-film on a wafer W may be discharged to the outside by the first pumping port 215 and the second pumping port 210, respectively.

The first pumping port 215 and the second pumping port 210 may be connected to different pumps. This is helpful to reduce problem which may be caused by which the source gas and the reaction gas may react with each other in the pump, so that particles or the like may be deposited inside the pump if the source gas and the reaction gas used for thin-film deposition are sucked by the same pump.

A power supplying unit 40 may supply power to the chamber 50. The power supplying unit 40 may be, but is not limited to, an AC power supplying unit.

A control portion 60 may be connected to the vacuum chamber 50. The control portion 60, for example, may send the vacuum chamber 50 a signal to control thin-film deposition processes carried out in the vacuum chamber 50. For example, the control portion 60 may receive a signal related to thin-film deposition processes from the vacuum chamber 50 and then may send a corresponding signal to the vacuum chamber 50 or other portions of the thin-film deposition equipment 10.

An example of a gas injection apparatus used in a thin-film deposition equipment according to an exemplary embodiment of the present disclosure will be described with reference to FIG. 3.

Referring to FIG. 3, the gas injection apparatus 1 according to an exemplary embodiment of the present disclosure may include a base plate 105, a first gas supplying region 110, a second gas supplying region 120, a third gas supplying region 130, a fourth gas supplying region 140 and the like.

The first to fourth gas supplying regions 110, 120, 130 and 140 may be disposed on a face of the base plate 105. The first to fourth gas supplying regions 110, 120, 130 and 140 may be disposed in this order in a circumferential direction, for example, the rotating direction of the susceptor 300 in FIG. 2.

The first gas supplying region 110 may include a first source gas supplying region 112, a second source gas supplying region 114, and a first gas separation region 113. The first source gas supplying region 112, the second source gas supplying region 114, and the first gas separation region 113 may be disposed on the base plate 105.

The first source gas supplying region 112, the first gas separation region 113, and the second source gas supplying region 114 may be disposed in this order in the circumferential direction, for example, the rotating direction of the susceptor 300 in FIG. 2.

The first gas separation region 113 may be disposed between the first source gas supplying region 112 and the second source gas supplying region 114. For example, the first source gas supplying region 112 and the second source gas supplying region 114 may be disposed closely on either side of the first gas separation region 113 in the circumferential direction, respectively.

The first source gas supplying region 112, the first gas separation region 113, and the second source gas supplying region 114 may include fan-shaped, upper faces 112u, 113u and 114u, respectively.

The first gas supplying region 110 may include first spray holes 110h formed on the upper face 112u of the first source gas supplying region 112, the upper face 114u of the second source gas supplying region 114, and the upper face 113u of the first gas separation region 113.

The first gas supplying region 110 may supply a source gas onto a wafer W. For example, the first source gas supplying region 112 and the second source gas supplying region 114 may supply a source gas onto a wafer W and/or the susceptor 300.

However, the first gas separation region 113 disposed between the first source gas supplying region 112 and the second source gas supplying region 114 may not supply a source gas onto a wafer W. Instead of supplying a source gas onto a wafer W, the first gas separation region 113 may spray a purge gas through the first spray holes 110h formed on the upper face 113u of the first gas separation region 113.

For example, the first gas supplying region 110 may supply a source gas, a purge gas and a source gas onto a wafer W.

During one cycle of thin-film deposition, the first gas supplying region 110 may supply a source gas a number of times, and thus a wafer W can be sufficiently exposed to the source gas. By doing so, the quality of films produced by the thin-film deposition equipment 10 can be improved.

For example, by placing the first gas separation region 113 that supplies a purge gas between the first source gas supplying region 112 and the second source gas supplying region 114, excessive source gas absorbed and/or provided on a wafer W can be easily discharged.

The third gas supplying region 130 may be spaced apart from the first gas supplying region 110. The third gas supplying region 130 may include a fan-shaped, upper face 130u.

The third gas supplying region 130 may include third spray holes 130h formed on the upper face 130u of the third gas supplying region. The third gas supplying region 130 may supply a reaction gas onto a wafer W and/or the susceptor 300 through the third spray holes 130h.

In the gas injection apparatus of some embodiments, the third gas supplying region 130 is disposed neither between the first source gas supplying region 112 and the first gas separation region 113 nor between the second source gas supplying region 114 and the first gas separation region 113. For example, in some embodiments a region to supply a reaction gas onto a wafer W is disposed neither between the first source gas supplying region 112 and the first gas separation region 113 nor between the second source gas supplying region 114 and the first gas separation region 113.

The second gas supplying region 120 and the fourth gas supplying region 140 may be disposed between the first gas supplying region 110 and the third gas supplying region 130, and between the third gas supplying region 130 and the first gas supplying region 110, respectively. For example, the second gas supplying region 120 may be disposed between the second source gas supplying region 114 and the third gas supplying region 130, while the fourth gas supplying region 140 may be disposed between the first source gas supplying region 112 and the third gas supplying region 130.

The second gas supplying region 120 may include a fan-shaped, upper face 120u. The fourth gas supplying region 140 may include a fan-shaped, upper face 140u.

The second gas supplying region 120 may include second spraying holes 120h formed on the upper face 120u of the second gas supplying region. The fourth gas supplying region 140 may include fourth spraying holes 140h formed on the upper face 140u of the fourth gas supplying region. The second gas supplying region 120 and the fourth gas supplying region 140 may supply a purge gas onto a wafer W and/or the susceptor 300 through the second spray holes 120h and the fourth spray holes 140h, respectively.

The second gas supplying region 120 and the fourth gas supplying region 140 may supply a purge gas to thereby separate the source gas supplied from the first gas supplying region 110 from the reaction gas supplied from the third gas supplying region 130.

The gas injection apparatus 1 may include a peripheral trench 155 formed along the circumferential direction. The peripheral trench 155 may have a ring shape, for example. The peripheral trench 155 may be disposed along the arc of the first gas supplying region 110, the arc of the second gas supplying region 120, the arc of the third gas supplying region 130, and the arc of the fourth gas supplying region 140.

Although at least one of the first pumping ports 215 may be located on a line extending in a radial direction of the first gas separation region 113 in FIGS. 1 and 3, this is merely illustrative.

Another example of the gas injection apparatus used in the thin-film deposition equipment according to an exemplary embodiment of the present disclosure will be described with reference to FIG. 4. Descriptions will be made focusing on the differences from those described above with respect to FIGS. 1 to 3.

Referring to FIG. 4, in a gas injection apparatus 2 according to another exemplary embodiment of the present disclosure, a third gas supplying region 130 may include a first reaction gas supplying region 132, a second reaction gas supplying region 134, and a second gas separation region 133.

The first reaction gas supplying region 132, the second reaction gas supplying region 134, and the second gas separation region 133 may be disposed on the base plate 105.

The first reaction gas supplying region 132, the second gas separation region 133, and the second reaction gas supplying region 134 may be disposed in this order in the circumferential direction, for example, the rotating direction of the susceptor 300 in FIG. 2.

The second gas separation region 133 may be disposed between the first reaction gas supplying region 132 and the second reaction gas supplying region 134. The first reaction gas supplying region 132 and the second reaction gas supplying region 134 may be disposed closely on either side of the second gas separation region 133 in the circumferential direction, respectively.

Neither of the first reaction gas supplying region 132 and the second reaction gas supplying region 134 is disposed between the first source gas supplying region 112 and the first gas separation region 113 or between the second source gas supplying region 114 and the first gas separation region 113.

The first reaction gas supplying region 132, the second gas separation region 133, and the second reaction gas supplying region 134 may include fan-shaped, upper faces 132u, 133u and 134u, respectively.

The third spray holes 130h may be formed on the upper face 132u of the first reaction gas supplying region 132, the upper face 133u of the second separation region 133, and the upper face 134u of the second reaction gas supplying region 134.

The third gas supplying region 130 may supply a reaction gas onto a wafer W. For example, the first reaction gas supplying region 132 and the second reaction gas supplying region 134 may supply a reaction gas onto a wafer W and/or the susceptor 300.

However, the second gas separation region 133 disposed between the first reaction gas supplying region 132 and the second reaction gas supplying region 134 may not supply a reaction gas onto a wafer W. Instead of supplying a reaction gas onto a wafer W, the second gas separation region 133 may spray a purge gas through the third spray holes 130h formed on the upper face 133u of the second gas separation region 133.

For example, the third gas supplying region 130 may supply a reaction gas, a purge gas and a reaction gas onto a wafer W.

The second gas supplying region 120 may be disposed between the second source gas supplying region 114 and the first reaction gas supplying region 132, and the fourth gas supplying region 140 may be disposed between the first source gas supplying region 112 and the second reaction gas supplying region 134.

During one cycle of thin-film deposition, the third gas supplying region 130 supplies a reaction gas a number of times, and thus a wafer W can be sufficiently exposed to the reaction gas. By doing so, the quality of films produced by the thin-film deposition equipment 10 can be improved.

In FIG. 1, one of the second pumping ports 210 is disposed between the second gas supplying region 120 and the third gas supplying region 130 and the other is disposed between the fourth gas supplying region 140 and the third gas supplying region 130. However, in a thin-film deposition equipment 10 employing the gas injection apparatus 2, an additional second pumping port 210 may be located on a line extending in a radial direction of the second gas separation region 133 or one of the second pumping ports 210 may be located on a line extending in a radial direction of the second gas separation region 133.

Yet another example of the gas injection apparatus used in the thin-film deposition equipment according to the exemplary embodiment of the present disclosure will be described with reference to FIGS. 5 to 7. Descriptions will be made focusing on the differences from those described above with respect to FIGS. 1 to 3.

Referring to FIGS. 5 to 7, in a gas injection apparatus 3 according to yet another exemplary embodiment of the present disclosure, the first gas separation region 113 may be a trench extending in a radial direction.

For example, while the first source gas supplying region 112 and the second source gas supplying region 114 protrude from the base plate 105, the first gas separation region 113 may not protrude from the base plate 105.

In the gas injection apparatus 3 according to this exemplary embodiment, the first gas separation region 113 may be defined by a radius side-wall 112rs of the first source gas supplying region and a radius side-wall 114rs of the second source gas supplying region, which face each other and extend in radial directions. The bottom of the first gas separation region 113 may be defined by a face of the base plate 105. The bottom of the first gas separation region 113 may have a fan shape, for example.

The first gas separation region 113 having a form of a trench may be directly connected to a central trench or depression 150. Also, the first gas separation region 113 may be directly connected to the peripheral trench 155. For example, the central trench or depression 150 may be connected to the peripheral trench 155 by the first gas separation region 113 having a form of a trench.

In FIG. 5, the first spray holes 110h are not formed on the first gas separation region 113. However, it is merely for convenience of illustration but is not limiting the scope of the disclosure.

For example, in case that the first spray holes 110h are not formed on the first gas separation region 113, the first gas separation region 113 may not spray a purge gas onto a wafer W, as shown in FIG. 6. On the other hand, in case that the first spray holes 110h are formed on the first gas separation region 113, the first gas separation region 113 may spray a purge gas onto a wafer W, as shown in FIG. 7.

Additionally, the first gas separation region 113 has a form of a trench extending in a radial direction, so that excessive source gas absorbed on a wafer W may be easily discharged. A detailed description thereof will be described below with reference to FIGS. 11 and 12.

Still another example of the gas injection apparatus used in the thin-film deposition equipment according to an exemplary embodiment of the present disclosure will be described with reference to FIGS. 8 to 10. Descriptions will be made focusing on the differences from those described above with respect to FIGS. 5 to 7. It is to be noted that a cross-sectional view taken along line B-B of FIG. 8 may be substantially identical to FIG. 6 or 7.

Referring to FIGS. 8 to 10, in a gas injection apparatus 4 according to this exemplary embodiment, a third gas supplying region 130 may include a first reaction gas supplying region 132, a second reaction gas supplying region 134, and a second gas separation region 133. The second gas separation region 133 may be a trench extending in a radial direction.

The first reaction gas supplying region 132, the second reaction gas supplying region 134, and the second gas separation region 133 may be disposed on the base plate 105. While the first reaction gas supplying region 132 and the second reaction gas supplying region 134 protrude from the base plate 105, the second gas separation region 133 may not protrude from the base plate 105.

The first reaction gas supplying region 132, the second gas separation region 133, and the second reaction gas supplying region 134 may be disposed in this order in the circumferential direction, for example, the rotating direction of the susceptor 300 in FIG. 2.

The first reaction gas supplying region 132 and the second reaction gas supplying region 134 may include fan-shaped, upper faces 132u and 134u, respectively. The third spray holes 130h may be formed on the upper face 132u of the first reaction gas supplying region 132 and on the upper face 134u of the second reaction gas supplying region 134.

In the gas injection apparatus 4 according to this exemplary embodiment, the second gas separation region 133 may be defined by a radius side-wall 132rs of the first reaction gas supplying region 132 and a radius side-wall 134rs of the second reaction gas supplying region 134, which face each other and extend in radial directions. The bottom of the second gas separation region 133 may be defined by a face of the base plate 105. The bottom of the second gas separation region 133 may have a fan shape, for example.

The second gas separation region 133 having a form of a trench may be directly connected to the central trench or depression 150. Also, the second gas separation region 133 may be directly connected to the peripheral trench 155. For example, the central trench or depression 150 may be connected to the peripheral trench 155 by the second gas separation region 133 having a form of a trench. For example, the first gas separation region 113 and the second gas separation region 133 in the form of a trench may be connected to each other through the center trench or depression 150.

The first reaction gas supplying region 132 and the second reaction gas supplying region 134 may supply a reaction gas onto a wafer W and/or the susceptor 300. The second gas separation region 133 disposed between the first reaction gas supplying region 132 and the second reaction gas supplying region 134 may not supply a reaction gas onto a wafer W.

In FIG. 8, the third spray holes 130h are not formed on the second gas separation region 133. However, it is merely for convenience of illustration but is not limiting the scope of the disclosure.

For example, in case that the third spray holes 130h are not formed on the second gas separation region 133, the second gas separation region 133 may not spray a purge gas onto a wafer W, as shown in FIG. 9. On the other hand, in case that the third spray holes 130h are formed on the second gas separation region 133, the second gas separation region 133 may spray a purge gas onto a wafer W, as shown in FIG. 10.

The second gas separation region 133 may have a form of a trench extending in a radial direction, so that excessive source gas absorbed on a wafer W may be easily discharged.

Another example of the gas injection apparatus used in the thin-film deposition equipment according to the exemplary embodiment of the present disclosure will be described with reference to FIGS. 11 to 14. Descriptions will be made focusing on the differences from those described above with respect to FIGS. 1 to 3.

Referring to FIGS. 11 to 14, a gas injection apparatus 5 according to this exemplary embodiment of the present disclosure may further include first to fourth trenches 115, 125, 135 and 145. The first to fourth trenches 115, 125, 135 and 145 may be extended in radial directions.

The first trench 115 may be disposed between the first gas supplying region 110 and the second gas supplying region 120. The first trench 115 may be disposed between the second source gas supplying region 114 and the second gas supplying region 120.

The second trench 125 may be disposed between the second gas supplying region 120 and the third gas supplying region 130. The third trench 135 may be disposed between the third gas supplying region 130 and the fourth gas supplying region 140.

Further, the fourth trench 145 may be disposed between the fourth gas supplying region 140 and the first gas supplying region 110. The fourth trench 145 may be disposed between the first source gas supplying region 112 and the fourth gas supplying region 140.

The first to fourth gas supplying regions 110, 120, 130 and 140 may protrude from a face of the base plate 105.

The first trench 115 may be defined by a radius side-wall 110rs of the first gas supplying region and a radius side-wall 120rs of the second gas supplying region, which face each other and extend in radial directions. The radius side-wall 110rs of the first gas supplying region defining the first trench 115 may be a side wall of the second source gas supplying region 114.

The second trench 125 may be defined by a radius side-wall 120rs of the second gas supplying region and a radius side-wall 130rs of the third gas supplying region, which face each other and extend in radial directions. The third trench 135 may be defined by a radius side-wall 130rs of the third gas supplying region and a radius side-wall 140rs of the fourth gas supplying region, which face each other and extend in radial directions.

The fourth trench 145 may be defined by a radius side-wall 110rs of the first gas supplying region and a radius side-wall 140rs of the fourth gas supplying region, which face each other and extend in radial directions. The radius side-wall 110rs of the first gas supplying region defining the fourth trench 145 may be a side wall of the first source gas supplying region 112.

The bottom of the first trench 115 may be defined by a face of the base plate 105. Further, the bottom of each of the second to fourth trenches 125, 135 and 145 may be defined by the face of the base plate 105.

The bottom of each of the first to fourth trenches 115, 125, 135 and 145 may have a fan shape.

The upper face of each of the first to fourth gas supplying regions 110, 120, 130 and 140 protrudes from the face of the base plate 105 while the bottom of each of the first to fourth trenches 115, 125, 135 and 145 may be the face of the base plate 105. Therefore, there is a level difference between the upper face of each of the first to fourth gas supplying regions 110, 120, 130 and 140 and the bottom of a respective one of the first to fourth trenches 115, 125, 135 and 145.

By means of the first to fourth trenches 115, 125, 135 and 145, the first to fourth gas supplying regions 110, 120, 130 and 140 can be spaced apart from one another.

The central trench or depression 150 may be directly connected to the first to fourth trenches 115, 125, 135 and 145 extending in radial directions. For example, each of the first to fourth trenches 115, 125, 135 and 145 may be directly connected to the central trench or depression 150.

The central trench or depression 150 and the first to fourth trenches 115, 125, 135 and 145 directly connected thereto may have, but is not limited to, a pinwheel-like shape.

The peripheral trench 155 may be directly connected to each of the first to fourth trenches 115, 125, 135 and 145 extending in radial directions. For example, the peripheral trench 155 may be connected to the central trench or depression 150 through the first to fourth trenches 115, 125, 135 and 145.

In FIG. 2 and FIG. 11, curtain gas supplied from the central spray hole 150h flows through the space between the top plate 100 and the core portion 305, and accordingly it may not flow along the face 300a of the susceptor on which a wafer W is loaded. The curtain gas supplied from the central spray hole 150h may flow toward the first pumping port 215 and/or the second pumping ports 210 through the first to fourth trenches 115, 125, 135 and 145 directly connected to the central trench or depression 150.

As such, by employing the gas injection apparatus including one or more trenches extending in radial directions, it can be prevented that the source gas supplied from the first gas supplying region 110 intermixes with the reaction gas supplied from the third gas supplying region 130. In addition, it may be prevented that the concentration of the source gas and/or the reaction gas is diluted that may be caused by the curtain gas.

As a result, it is possible to reduce processing defects that may occur at locations adjacent to the core portion 305 on a wafer W due to the diluted concentration of the reaction gas.

In FIG. 12, additional gas spray holes are not formed on the bottom of each of the first to fourth trenches 115, 125, 135 and 145. However, it is merely for convenience of illustration but is not limiting the scope of the disclosure.

For example, in case that spray holes are not formed on the bottom of each of the first to fourth trenches 115, 125, 135 and 145, no purge gas may be sprayed from the bottom of each of the first to fourth trenches 115, 125, 135 and 145 onto a wafer W, as shown in FIG. 13. On the other hand, when spray holes are formed on the bottom of each of the first to fourth trenches 115, 125, 135 and 145, a purge gas may be sprayed from the bottom of each of the first to fourth trenches 115, 125, 135 and 145 onto a wafer W, as shown in FIG. 14.

By forming the first to fourth trenches 115, 125, 135 and 145 between every two regions of the first to fourth gas supplying regions 110, 120, 130 and 140, respectively, the source gas and/or the reaction gas which did not contribute to forming a thin-film on a wafer W may quickly exit through the first to fourth trenches 115, 125, 135 and 145. Such source gas and/or reaction gas may quickly exit through the first to fourth trenches 115, 125, 135 and 145 because the fluid conductance (first conductance) between each of the first to fourth trenches 115, 125, 135 and 145 and the susceptor 300 is larger than the fluid conductance (second conductance) between each of the first to fourth gas supplying regions 110, 120, 130 and 140 and the susceptor 300.

Another example of the gas injection apparatus used in the thin-film deposition equipment according to the exemplary embodiment of the present disclosure will be described with reference to FIG. 15. Descriptions will be made focusing on the differences from those described above with respect to FIGS. 11 to 14.

Referring to FIG. 15, in a gas injection apparatus 6 according to another exemplary embodiment of the present disclosure, a third gas supplying region 130 may include a first reaction gas supplying region 132, a second reaction gas supplying region 134, and a second gas separation region 133.

The first reaction gas supplying region 132, the second gas separation region 133, and the second reaction gas supplying region 134 may be disposed in this order in the circumferential direction, for example, the rotating direction of the susceptor 300 in FIG. 2.

The third gas supplying region 130 may supply a reaction gas onto a wafer W. For example, the first reaction gas supplying region 132 and the second reaction gas supplying region 134 may supply a reaction gas onto a wafer W and/or the susceptor 300.

However, the second gas separation region 133 disposed between the first reaction gas supplying region 132 and the second reaction gas supplying region 134 may not supply a reaction gas onto a wafer W. Instead of supplying a reaction gas onto a wafer W, the second gas separation region 133 may spray a purge gas through the third spray holes 130h formed on the upper face 133u of the second gas separation region.

For example, the third gas supplying region 130 may supply a reaction gas, a purge gas and a reaction gas onto a wafer W.

The second trench 125 may be disposed between the second gas supplying region 120 and the first reaction gas supplying region 132. The third trench 135 may be disposed between the fourth gas supplying region 140 and the second reaction gas supplying region 134.

Another example of the gas injection apparatus used in the thin-film deposition equipment according to the exemplary embodiment of the present disclosure will be described with reference to FIG. 16. Descriptions will be made focusing on the differences from those described above with respect to FIG. 15.

A cross-sectional view taken along line B-B of FIG. 16 may be substantially identical to FIG. 6 or FIG. 7. A cross-sectional view taken along line C-C of FIG. 16 may be substantially identical to FIG. 9 or FIG. 10.

Referring to FIG. 16, in a gas injection apparatus 7 according to yet another exemplary embodiment of the present disclosure, each of the first gas separation region and the second gas separation region 113 and 133 may be a trench extending in a radial direction.

The first gas separation region 113 may be defined by a radius side-wall of the first source gas supplying region 112 and a radius side-wall of the second source gas supplying region 114, which face each other and extend in radial directions. The bottom of the first gas separation region 113 may be defined by a face of the base plate 105.

Likewise, the second gas separation region 133 may be defined by a radius side-wall of the first source gas supplying region 132 and a radius side-wall of the second source gas supplying region 134, which face each other and extend in radial directions. The bottom of the second gas separation region 133 may be defined by the face of the base plate 105.

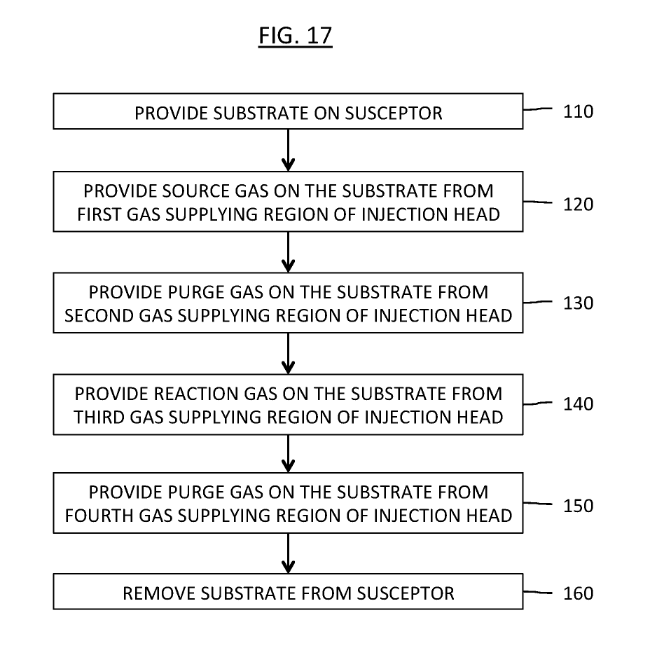

FIG. 17 is a flowchart illustrating a method of manufacturing an electronic device according to an embodiment of the disclosure. For example, FIG. 17 may represent a process for manufacturing a semiconductor device.

According to the present embodiment, any one of the film deposition equipment including a gas injection head and a susceptor described above may be used. Therefore, duplicated description may be omitted.

Referring to FIG. 17, in step S110, a substrate is provided on a susceptor of a thin film deposition equipment. The substrate may be a wafer, and may be a silicon substrate, a germanium substrate, a silicon germanium substrate, etc. In step S120, a source gas may be provided on the substrate from a first gas supplying region of a gas injection head of the thin film deposition equipment. Some of the source gas may be absorbed on the surface of the substrate, and remaining gas which is not absorbed on the surface of the substrate may be discharged through a recess formed on the gas injection head and a pumping port formed in the thin film deposition equipment.

In step S130, a purge gas is provided on the substrate from a second gas supplying region of the gas injection head. The purge gas may be helpful to remove the source gas which is not absorbed on the surface of the substrate. The purge gas may be discharged via a recess formed on the gas injection head and a pumping port formed in the thin film deposition equipment. The recess and/or the pumping port of this step may be the same as or different from the recess and/or the pumping port of the step S120. The purge gas may be inert gas that does not undergo gas-phase reaction with the source gas. The purge gas may be, but is not limited to, nitrogen gas.

In step S140, a reaction gas is provided on the substrate from a third gas supplying region of the gas injection head. The reaction gas may react with the source gas absorbed on the surface of the substrate to form a layer on the substrate. Remaining reaction gas which is not reacted with the source gas may be discharged through a recess formed on the gas injection head and a pumping port formed in the thin film deposition equipment. The recess and/or the pumping port of this step may be the same as or different from the recess and/or the pumping port of the step S120 or the step S130.

In step S150, a purge gas may be provided on the substrate from a fourth gas supplying region of the gas injection head. The purge gas may be helpful to remove the source gas which is not absorbed on the surface of the substrate and/or the reaction gas which is not reacted with the source gas. The purge gas may be discharged via a recess formed on the gas injection head and a pumping port formed in the thin film deposition equipment. The recess and/or the pumping port of this step may be the same as or different from the recess and/or the pumping port of the step S120, S130, or S140. The purge gas may be inert gas that does not undergo gas-phase reaction with the source gas. The purge gas may be, but is not limited to, nitrogen gas. In step S160, the substrate is removed from the susceptor.

In certain embodiments, some of the steps in FIG. 17 may be omitted in manufacturing an electronic device. In certain embodiments, one or more additional steps, such as forming integrated circuits on the substrate, forming semiconductor devices using the substrate, and singulating the semiconductor devices from the substrate to form a plurality of semiconductor devices such as chips, may be performed in addition to the steps of FIG. 17 to manufacture an electronic device.

The embodiments of the present inventive concept have been described with reference to the attached drawings, but it may be understood by one of ordinary skill in the art that the present inventive concept may be performed in other specific forms without changing the technical concept or essential features of the present inventive concept. Further, the above-described embodiments are merely examples and do not limit the scope of the rights of the present inventive concept.

1. An apparatus comprising:
a base plate;
a first gas separation region on the base plate;
first and second source gas supplying regions disposed on the base plate on either side of the first gas separation region, respectively, and configured to supply a source gas; and
a first reaction gas supplying region disposed at a position on the base plate other than between the first gas separation region and the first source gas supplying region or between the first gas separation region and the second source gas supplying region, and configured to supply a reaction gas,
wherein the first source gas supplying region and the second source gas supplying region protrude from the base plate,
wherein each of the first source gas supplying region and the second source gas supplying region has a fan-shaped, upper face, and
wherein the first gas separation region is defined by a side wall of the first source gas supplying region and a side wall of the second source gas supplying region, the side walls facing each other and extending in radial directions.

2. The apparatus of claim 1, wherein the first gas separation region is configured to supply a purge gas.

3. The apparatus of claim 1, further comprising:
a second reaction gas supplying region disposed at a position other than between the first gas separation region and the first source gas supplying region or between the first gas separation region and the second source gas supplying region; and
a second gas separation region disposed between the first reaction gas supplying region and the second reaction gas supplying region,
wherein the second reaction gas supplying region is configured to supply a reaction gas.

4. The apparatus of claim 3, wherein the second gas separation region is configured to supply a purge gas.

5. The apparatus of claim 3, wherein the first reaction gas supplying region and the second reaction gas supplying region protrude from the base plate,
wherein an upper face of the first reaction gas supplying region and an upper face of the second reaction gas supplying region have fan shapes, and
wherein the second gas separation region is defined by a side wall of the first reaction gas supplying region and a side wall of the second reaction gas supplying region, the side walls facing each other and extending in radial directions.

6. The apparatus of claim 1, further comprising:
a second gas separation region disposed between the first source gas supplying region and the first reaction gas supplying region; and
a third gas separation region disposed between the second source gas supplying region and the first reaction gas supplying region,
wherein the second gas separation region and the third gas separation region are configured to supply a purge gas.

7. The apparatus of claim 6, further comprising:
a first trench extending in a radial direction between the second gas separation region and the first source gas supplying region and having the base plate as its bottom;
a second trench extending in a radial direction between the third gas separation region and the second source gas supplying region and having the base plate as its bottom;
a third trench extending in a radial direction between the second gas separation region and the first reaction gas supplying region and having the base plate as its bottom; and
a fourth trench extending in a radial direction between the third gas separation region and the first reaction gas supplying region and having the base plate as its bottom.

8. The apparatus of claim 1, further comprising:
a vacuum chamber including the base plate and a susceptor opposite to the base plate,
wherein the susceptor is configured to rotate in the vacuum chamber and has a portion configured to load a wafer on a face of the susceptor.

9. An apparatus comprising:
a base plate including first to fourth gas supplying regions disposed on the base plate arranged sequentially in a circumferential direction;
a first trench extending in a radial direction between the first gas supplying region and the second gas supplying region and having the base plate as its bottom;
a second trench extending in a radial direction between the second gas supplying region and the third gas supplying region and having the base plate as its bottom;
a third trench extending in a radial direction between the third gas supplying region and the fourth gas supplying region and having the base plate as its bottom;
a fourth trench extending in a radial direction between the fourth gas supplying region and the first gas supplying region and having the base plate as its bottom; and
a central trench surrounded by the first to fourth gas supplying regions and having its bottom defined by the base plate,
wherein the first gas supplying region supplies a source gas, the third gas supplying region supplies a reaction gas, and the second and fourth gas supplying regions supply a purge gas, and
wherein the first gas supplying region comprises: first and second source gas supplying regions for supplying the source gas, and a first gas separation region disposed between the first source gas supplying region and the second source gas supplying region and configured not to supply the source gas.

10. The apparatus of claim 9, wherein the first gas separation region is configured to supply the purge gas.

11. The apparatus of claim 9, wherein the third gas supplying region comprises first and second reaction gas supplying regions and a second gas separation region,
wherein the first and second reaction gas supplying regions are configured to supply the reaction gas, and
wherein the second gas separation region is disposed between the first reaction gas supplying region and the second reaction gas supplying region and is configured not to supply the reaction gas.

12. The apparatus of claim 11, wherein the first gas separation region and the second gas separation region are configured to supply the purge gas.

13. The apparatus of claim 9, wherein the purge gas is supplied from the bottom of each of the first to fourth trenches.

14. An apparatus comprising:
a vacuum chamber comprising a top plate and a body; and
a susceptor installed in the vacuum chamber, configured to rotate therein, and having a portion configured to load a wafer on a first face,
wherein the top plate comprises:
a base plate facing the susceptor and having a second face opposite to the first face of the susceptor;
first to fourth regions disposed on the second face of the base plate arranged sequentially in a rotating direction of the susceptor;
a first recess extending in a radial direction between the first region and the second region and having the base plate as its bottom;
a second recess extending in a radial direction between the second region and the third region and having the base plate as its bottom;
a third recess extending in a radial direction between the third region and the fourth region and having the base plate as its bottom; and
a fourth recess extending in a radial direction between the fourth region and the first region and having the base plate as its bottom,
wherein the first region is configured to supply a source gas onto the first face of the susceptor, the third region is configured to supply a reaction gas onto the first face of the susceptor, and the second and fourth regions are configured to supply a purge gas,
wherein the first region comprises: first, second, and third sub-regions arranged sequentially in the rotating direction of the susceptor, and
wherein the first and third sub-regions are configured to supply the source gas onto the first face of the susceptor, while the second sub-region does not supply the source gas.

15. The apparatus of claim 14, wherein the third region comprises first, second and third sub-regions arranged sequentially in the rotating direction of the susceptor, and
wherein the first and third sub-regions are configured to supply the reaction gas onto the first face of the susceptor while the second sub-region does not supply the reaction gas.

16. The apparatus of claim 15, wherein the second sub-regions of the first and third regions are configured to supply a purge gas.

17. The apparatus of claim 16, wherein the second and fourth regions are configured to supply a purge gas.

18. The apparatus of claim 17, wherein the top plate further comprises a fifth recess in the center portion of the top plate, and the first to fourth recesses are connected to each other via the fifth recess.

19. The apparatus of claim 18, wherein the first to fourth regions are fan-shaped.

20. The apparatus of claim 19, wherein the first to fourth recesses are fan-shaped, and the fifth recess is circular.

21-40. (canceled)
